(19) United States
(12) Patent Application Publication
(10) Pub. No.: US 2024/0213021 A1
(43) Pub. Date: Jun. 27, 2024

(54) METHOD FOR PREPARING SEMICONDUCTOR LAYER

(71) Applicant: NATIONAL TAIWAN UNIVERSITY, Taipei (TW)

(72) Inventors: Yi-Chia CHOU, Taipei City (TW); Chang-Hsun HUANG, Taipei City (TW)

(21) Appl. No.: 18/109,430

(22) Filed: Feb. 14, 2023

(30) Foreign Application Priority Data
Dec. 21, 2022 (TW) 111149183

(51) Int. Cl. H01L 21/02; H01L 21/324

(52) U.S. Cl. CPC H01L 21/0254; H01L 21/02076; H01L 21/02381; H01L 21/02546; H01L 21/3245

(57) ABSTRACT

A method for preparing a semiconductor layer comprises the following steps: providing a mica substrate; depositing a plurality of semiconductor films on the mica substrate to form a semiconductor substrate; and cooling the semiconductor substrate at a cooling rate to separate the plurality of semiconductor films from the mica substrate to obtain a semiconductor layer, wherein the cooling rate ranges from 10° C./min to 50° C./min. Herein, the plurality of semiconductor films comprise a first semiconductor film and a second semiconductor film, the first semiconductor film is formed at a first temperature, the second semiconductor film is formed at a second temperature, the first temperature is lower than the second temperature, and the first semiconductor film is disposed between the mica substrate and the second semiconductor film.

### CROSS-REFERENCE TO RELATED APPLICATIONS

This application claims the benefits of the Taiwan Patent Application Serial Number 111149183, filed on Dec. 21, 2022, the subject matter of which is incorporated herein by reference.

### BACKGROUND OF THE INVENTION

### Field

The present invention relates to a method for preparing a semiconductor layer. More specifically, the present invention relates to a method for growing a self-separating semiconductor layer.

### Description of Related Art

At present, alumina substrates are commonly used as the substrates for growing semiconductor layers. However, the cost of the alumina substrates is much higher than that of silicon substrates, and the alumina substrates are not easy to integrate with the mature silicon semiconductor industry. Thus, the market development of the alumina substrates is limited.

On the other hand, growing the semiconductor layers on the silicon substrates has the advantages of low cost, large area, and high thermal conductivity, and can be combined with the highly mature silicon semiconductor industry. However, the lattice mismatch and the difference in thermal expansion coefficients between the silicon substrate and some semiconductor layers may cause defects or even cracks of the formed semiconductor layers if the semiconductor layers are directly grown on the silicon substrate, resulting in the technical obstacles to the growth of the semiconductor layers using the hetero-epitaxy technology.

Currently, the techniques using sapphire substrates and silicon carbide substrates to grow semiconductor layers are also developed, but their complex manufacturing processes and low success rates cause the high production costs and other issues.

Therefore, the present invention provides a method for preparing a semiconductor layer to effectively overcome the above-mentioned problems.

### SUMMARY OF THE INVENTION

According to one aspect of the present invention, a method for preparing a semiconductor layer is provided, which comprises the following steps: providing a mica substrate; depositing a plurality of semiconductor films on the mica substrate to form a semiconductor substrate; and cooling the semiconductor substrate at a cooling rate to separate the plurality of semiconductor films from the mica substrate to obtain a semiconductor layer, wherein the cooling rate ranges from 10° C./min to 50° C./min (for example, the cooling rate ranges from 10° C./min to 30° C./min). Herein, the plurality of semiconductor films comprise a first semiconductor film and a second semiconductor film, the first semiconductor film is formed at a first temperature, the second semiconductor film is formed at a second temperature, the first temperature is lower than the second temperature, and the first semiconductor film is disposed between the mica substrate and the second semiconductor film. In the present invention, the deposition of the plurality of semiconductor films on the mica substrate can be achieved through van der Waals force heteroepitaxy.

In one embodiment of the present invention, the first semiconductor film and the second semiconductor film may respectively be a gallium nitride (GaN) film or a gallium arsenide (GaAs) film, but the present invention is not limited thereto. In another embodiment of the present invention, the first semiconductor film and the second semiconductor film may respectively be a GaN film, but the present invention is not limited thereto.

In one embodiment of the present invention, the first temperature may range from 500° C. to 700° C. For example, the first temperature may range from 500° ° C. to 650° C. or from 550° C. to 650° C.; or, for example, the first temperature may be about 600° C. The second temperature may range from 700° C. to 1200° ° C. For example, the second temperature may range from 800° ° C. to 1100° C. or from 850° ° C. to 1000° C.; or, for example, the second temperature may be about 950° ° C. However, the present invention is not limited thereto.

In addition, before the step of depositing the plurality of semiconductor films on the mica substrate, the method of the present invention may further comprise a step of: introducing an ammonia gas for a predetermined time. Herein, the predetermined time may range from 5 minutes to 15 minutes. For example, the predetermined time may range from 7 minutes to 13 minutes, or the predetermined time may be about 10 minutes. However, the present invention is not limited thereto. Introducing the ammonia gas can stabilize and ammoniate the surface of the mica substrate.

On the other hand, the step of deposition GaN films as the semiconductor films may be performed in a chamber. Therefore, the method of the present invention may further comprise a step of: depositing GaN films in a chamber. The pressure of the chamber may ranges from 100 torr to 760 torr, from 300 torr to 760 torr, from 500 torr to 760 torr or from 600 torr to 760 torr. In one embodiment, the pressure of the chamber may be about 700 torr. However, the present invention is not limited thereto.

In addition, the method of the present invention may further comprise a step of: introducing a gas into the chamber, wherein the gas may include ammonia, hydrogen chloride and carrier gas, but the present invention is not limited thereto. In addition, the aforesaid carrier gas may include hydrogen, nitrogen or a combination thereof. When the carrier gas comprises hydrogen and nitrogen, the ratio of hydrogen to nitrogen may range from 1:10 to 10:1. For example, the ratio of hydrogen to nitrogen may be about 1:1

In one embodiment of the present invention, the thickness of the first semiconductor film is 400 nm, and the thickness of the second semiconductor film is 300 μm. In one embodiment of the present invention, a thickness of the plurality of semiconductor films is 10% to 1500% of a thickness of the mica substrate. For example, the thickness of the plurality of semiconductor films is 10% to 1200% or 10% to 1000% of the thickness of the mica substrate. Herein, the thickness of the mica substrate may range from 10 μm to 100 μm, for example, from 20 μm to 80 μm, from 20 μm to 50 μm or from 20 μm to 30 μm.

In one embodiment of the present invention, the first semiconductor film and the second semiconductor film may be respectively formed by hydride vapor phase epitaxy (HVPE). However, the present invention is not limited thereto, and the first semiconductor film and the second semiconductor film may be formed by other methods according to the desired properties of the first semiconductor film and the second semiconductor film.

In one embodiment, the method of the present invention may further comprise a step of cleaning the mica substrate after the step of separating the plurality of semiconductor films from the mica substrate. For example, the mica substrate may be cleaned by soaking, so as to reuse the used mica substrate to save production costs.

Other novel features of the present invention will become more apparent from the following detailed description when taken in conjunction with the accompanying drawings.

### BRIEF DESCRIPTION OF DRAWINGS

FIG. 1 is a schematic view showing a method for preparing a semiconductor layer according to the present invention.

FIG. 2 is a schematic view showing a method for cleaning a used mica substrate according to the present invention.

### DETAILED DESCRIPTION OF THE INVENTION

Different embodiments of the present invention are provided in the following description. These embodiments are meant to explain the technical content of the present invention, but not meant to limit the scope of the present invention.

It should be noted that, in the present specification, when a component is described to have an element, it means that the component may have one or more of the elements, and it does not mean that the component has only one of the element, except otherwise specified.

Moreover, in the present specification, the ordinal numbers, such as “first” or “second”, are used to distinguish a plurality of elements having the same name, and it does not mean that there is essentially a level, a rank, an executing order, or a manufacturing order among the elements, except otherwise specified. A “first” element and a “second” element may exist together in the same component, or alternatively, they may exist in different components, respectively. The existence of an element described by a greater ordinal number does not essentially mean the existent of another element described by a smaller ordinal number.

In the present specification, except otherwise specified, the feature A “or” or “and/or” the feature B means the existence of the feature A, the existence of the feature B, or the existence of both the features A and B. The feature A “and” the feature B means the existence of both the features A and B. The term “comprise(s)”, “comprising”, “include(s)”, “including”, “have”, “has” and “having” means “comprise(s)/comprising but is/are/being not limited to”.

Moreover, in the present specification, the terms, such as “top”, “bottom”, “left”, “right”, “front”, “back”, or “middle”, as well as the terms, such as “on”, “above”, “under”, “below”, or “between”, are used to describe the relative positions among a plurality of elements, and the described relative positions may be interpreted to include their translation, rotation, or reflection.

Moreover, in the present specification, when an element is described to be arranged “on” another element, it does not essentially mean that the elements contact the other element, except otherwise specified. Such interpretation is applied to other cases similar to the case of “on”.

Method for Preparing Semiconductor Layer

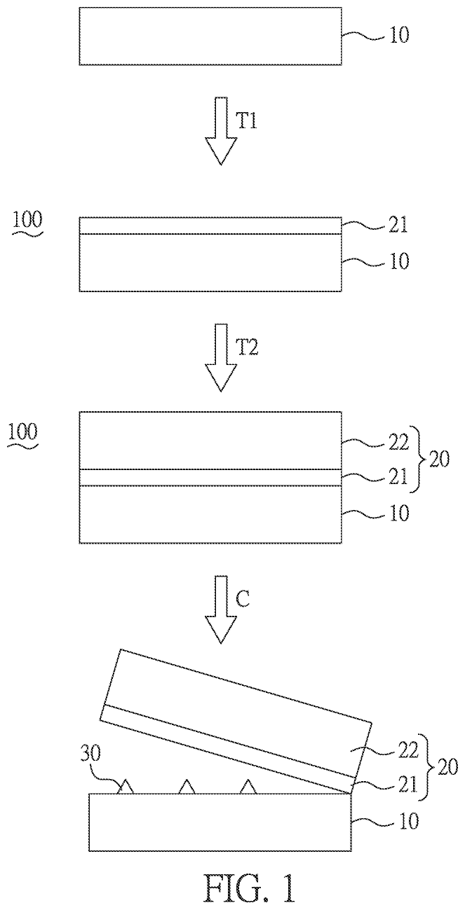

As shown in FIG. 1, the method for preparing a semiconductor layer of the present invention comprises the following steps: providing a mica substrate 10; depositing a plurality of semiconductor films on the mica substrate 10 through van der Waals force heteroepitaxy to form a semiconductor substrate 100, wherein the plurality of semiconductor films comprises a first semiconductor film 21 and a second semiconductor film 22; and cooling the semiconductor substrate 100 at a cooling rate C to separate the first semiconductor film 21 and the second semiconductor film 22 from the mica substrate 10 to obtain a semiconductor layer 20. Herein, the cooling rate C ranges from 10° C./min to 50° C./min, the first semiconductor film 21 is formed at a first temperature T1, the second semiconductor film 22 is formed at a second temperature T2, the first temperature T1 is lower than the second temperature T2, and the first semiconductor film 21 is disposed between the mica substrate 10 and the second semiconductor film 22.

In the present embodiment, GaN films grown on the mica substrate is provided as an example, and the preparation method thereof comprises the following steps.

First, a commercially available 2-inch artificial mica sheet was teared with a pointed tweezer to form a mica substrate 10 with the thickness of about 20 μm to 30 μm. Next, the surface of the mica substrate 10 was cleaned with alcohol and dried by using a nitrogen gun. The cleaned mica substrate 10 was placed into the chamber of hydride vapor phase epitaxy (HVPE), the pressure was maintained at 700 torr, and the first semiconductor film 21 and the second semiconductor film 22 were respectively formed on the mica substrate 10 in two stages of the first temperature T1 and the second temperature T2. The first semiconductor film 21 was used to improve the quality and nucleation difficulty of the second semiconductor film 22. The carrier gas used in the whole process was hydrogen and nitrogen, and the ratio of hydrogen to nitrogen was 1:1. Before forming the first semiconductor film 21, ammonia gas was introduced for 10 minutes to stabilize the flow and ammoniate the surface of the mica substrate 10. After the ammonia gas was introduced, a mixed gas of hydrogen chloride and ammonia was introduced for epitaxy to form the first semiconductor film 21. The epitaxy time was 10 minutes, the flow rates of ammonia and hydrogen chloride were respectively 670 sccm and 47 sccm, and the V/III ratio was 14.25. Next, before forming the second semiconductor film 22, ammonia gas was also introduced for 10 minutes, and then a mixed gas of hydrogen chloride and ammonia was introduced for epitaxy to form the second semiconductor film 22. The epitaxy time was 180 minutes, the flow rates of hydrogen chloride and ammonia were respectively 67 sccm and 2500 sccm, and the V/III ratio was 37.31.

Because a horizontal hydride vapor phase epitaxy machine was used in the present embodiment, the grown film may have a problem of uneven thickness as the growth time increased. Thus, after growing for 1.5 hours, the temperature was slowly decreased, and the mica substrate 10 was rotated 180 degrees and then grown for another 1.5 hours, for a total of 3 hours. After the growth was completed, the temperature of the semiconductor substrate 100 was rapidly decreased at a rate of 10° C./min, so that the first semiconductor film 21 and the second semiconductor film 22 were self-separated from the mica substrate 10 to form the semiconductor layer 20 of the present embodiment.

In the present embodiment, the first semiconductor film 21 and the second semiconductor film 22 were GaN films, the first temperature was 600° C., the second temperature T2 was 950° C., and the thicknesses of the grown first semiconductor film 21 and the grown second semiconductor film were about 0.4 μm and 300 μm.

Method for Cleaning Mica Substrate

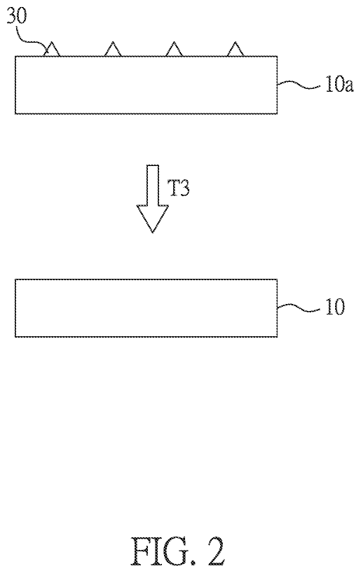

As shown in FIG. 2, the method for cleaning the used mica substrate 10a comprises the following steps. The used mica substrate 10a was immersed into deionized water at 80ºC for 4 hours to remove the semiconductor islands 30 (i.e. gallium nitride islands) on the used mica substrate 10a to form a clean mica substrate 10. The clean mica substrate 10 can be reused, and put into a hydride vapor phase epitaxy machine again to grow another self-separated semiconductor layer 20 according to the above-mentioned method for preparing the semiconductor layer (as shown in FIG. 1).

In conclusion, the method for preparing the semiconductor layer of the present invention has the advantages of high success rate and low cost, and the semiconductor layer is grown on the mica substrate by epitaxy through van der Waals force. Thus, the impact caused by the lattice mismatch between the mica substrate and the semiconductor layer can be reduced. In addition, the semiconductor layer can self-separate from the mica substrate during rapid cooling, so the preparation method of the semiconductor layer can be simplified. On the other hand, after proper cleaning, the mica substrate can be reused, and the cost of the substrate can be greatly reduced. Therefore, the present invention provides a novel method for preparing the semiconductor layer.

Although the present invention has been explained in relation to its embodiment, it is to be understood that many other possible modifications and variations can be made without departing from the spirit and scope of the disclosure as hereinafter claimed.

1. A method for preparing a semiconductor layer, comprising the following steps:
providing a mica substrate;
depositing a plurality of semiconductor films on the mica substrate to form a semiconductor substrate; and
cooling the semiconductor substrate at a cooling rate to separate the plurality of semiconductor films from the mica substrate to obtain a semiconductor layer, wherein the cooling rate ranges from 10° C./min to 50° C./min,
wherein the plurality of semiconductor films comprise a first semiconductor film and a second semiconductor film, the first semiconductor film is formed at a first temperature, the second semiconductor film is formed at a second temperature, the first temperature is lower than the second temperature, and the first semiconductor film is disposed between the mica substrate and the second semiconductor film.

2. The method of claim 1, wherein the first semiconductor film and the second semiconductor film respectively are a GaN film or a GaAs film.

3. The method of claim 1, wherein the first semiconductor film and the second semiconductor film respectively are a GaN film.

4. The method of claim 3, wherein the first temperature ranges from 500° C. to 700° C., and the second temperature ranges from 850° C. to 1000° C.

5. The method of claim 1, further comprising a step of: introducing an ammonia gas for a predetermined time before the step of depositing the plurality of semiconductor films on the mica substrate.

6. The method of claim 5, wherein the predetermined time ranges from 5 minutes to 15 minutes.

7. The method of claim 1, wherein a thickness of the plurality of semiconductor films is 10% to 1500% of a thickness of the mica substrate.

8. The method of claim 1, wherein the cooling rate ranges from 10° C./min to 30° C./min.

9. The method of claim 1, wherein the first semiconductor film and the second semiconductor film are respectively formed by hydride vapor phase epitaxy (HVPE).

10. The method of claim 1, further comprising a step of cleaning the mica substrate after the step of separating the plurality of semiconductor films from the mica substrate.

11. The method of claim 1, wherein a thickness of the first semiconductor film is 400 nm.

12. The method of claim 1, wherein a thickness of the second semiconductor film is 300 μm.
